(19) United States
(12) Patent Application Publication
(10) Pub. No.: US 2006/0278976 A1
(43) Pub. Date: Dec. 14, 2006

(54) Semiconductor device, method and manufacturing same, identification label and information carrier

(75) Inventors: Ronald Dekker, Eindhoven (DE); Theodorus Martinus Michielsen, Eindhoven (NL); Antoon Marie Henrie Tombeur, Eindhoven (NL); Johann-Heinrich Fock, Hamburg (DE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: koninklijke phillips electronics n.c.

(21) Appl. No.: 10/572,982

(22) PCT Filed: Sep. 2, 2004
(86) PCT No.: PCT/IB04/51676

§ 371 Date: Mar. 21, 2006

(51) Int. Cl. H01L 23/34

(52) U.S. Cl. 257/724

(57) ABSTRACT

The semiconductor device (100) comprises an integrated circuit (20) and a first and a second contact face (31,33). These are connected with vertical interconnects (32,34) to the integrated circuit (20). This integrated circuit (20) is present in a semiconductor layer of a substrate. This substrate is absent in a non-active area (B). This leads to the fact that on the side faces (101) of the device (100) neither conductive material nor parts of the semiconductor substrate are exposed. On lamination of the device between two metallized foils into an identification label, the risk of short-circuitry due to undesired contact at the side face (101) of the device (100), is prevented thereby.

The invention relates to a semiconductor device having a first and an opposite second side, comprising:

a substrate comprising a semiconductor layer and an electrically insulating layer and being present on the first side of the device;

an integrated circuit provided with a plurality of semiconductor elements, which are defined in or on the semiconductor layer and are interconnected according to a desired pattern in an interconnect structure;

a first contact face that is present on the first side of the device, and

a second contact face that is present on the second side of the device, and is connected to the interconnect structure.

The invention also relates to a method of manufacturing such a semiconductor device.

The invention further relates to an identification label and an information carrier comprising such a semiconductor device.

Such a semiconductor device is known from WO-A 02/075647. The known device is an integrated circuit that is provided on its opposite sides with electrically conductive contact faces. The integrated circuit is—according to conventional technology—defined in a silicon substrate layer, on surface of which an electrically insulating layer is present. This insulating layer is generally a thermal oxide layer. This structure has the advantage that the assembly in an identification label is simplified: the first and the second side can be exchanged.

It is a disadvantage of the known device, that it is less suitable for assembly in a metal strip. Such a metal strip will cover not only one of the first and second sides of the device, but also any side faces. This may lead to leakage currents and parasitic effects, particularly at higher frequencies, for the semiconductor elements in the substrate.

It is therefore a first object of the invention to provide a semiconductor device of the kind mentioned in the opening paragraph, which is less sensitive to parasitic effects during assembly in a metal strip.

This object is achieved in that:

an electrically insulating support layer is present, which covers on the second side the integrated circuits and extends laterally around the integrated circuit in a non-active area, through which support layer a vertical interconnect is present to connect the second contact face with the interconnect structure;

the semiconductor layer is laterally partially removed so as to be absent in the non-active area, and

the first contact face is connected to the interconnect structure through a vertical interconnect.

The integrated circuit in the device of the invention is in fact an island within an encapsulation, that is electrically insulating at least for the larger part and except for the vertical interconnects. Due to this island-like structure and the vertical interconnects, there is no risk of the semiconductor substrate or any interconnects on a side face coming into contact with any metal foil. Then any uncontrollable and undesired effects giving rise to degraded functioning or even malfunctioning are prevented in this way.

The non-active area of the device is an area laterally around an active area in which the integrated circuit is defined. The non-active area and the active area may be complementary to fill the complete surface area of the device. However, it is not excluded that there is an intermediate area between the active and the non-active area The non-active area is then an edge area Already herewith, the object of the invention to prevent any short-circuitry during lamination is achieved.

It is an advantage of the device of the invention, that the thickness of the substrate can be reduced without imparing the stability of the device. In fact, the support layer take over the function of support from the semiconductor substrate. As the support layer can be chosen freely, this allows the device as a whole to be bendable or even completely flexible.

It is another advantage, as a consequence of the thinning, that the device can be completely or largely transparent. This feature is advantageous in view of the possible security functions.

It is a further advantage of the limitation of the semiconductor layer of the substrate to certain islands that individual devices can be easily separated from each other: there need not be any ceramic material or metal that must be cut through.

In a suitable embodiment, the vertical interconnect to the first contact face is present in the non-active area, the first contact face being defined in an electrically conducting layer. The presence of the first contact face in a separate layer, instead of as a highly doped zone on the second side of the substrate, reduces the resistance from the contact face to the actual circuit. It furthermore reduces the risk of undesired interaction between the vertical interconnect through the substrate and neighboring semiconductor elements.

In a preferred embodiment, the electrically insulating layer is laterally substantially continuous so as to be present in the non-active area Particularly, this insulating layer extends through the complete device from the one side face to the opposite side face. Such a continuous presence is not only beneficial to the stability of the device; it is also an effective barrier layer—particularly an etch stop layer—during processing. The effectiveness is large, in that it can be used as such both during the processing from the first side, and from the second side. Furthermore, the insulating layer, which is or comprises oxide by preference, allows to establish adequate adhesion with the organic layers.

The semiconductor device of the present invention can be provided in at least two technologies. In the first technology, use is made of a monocrystalline semiconductor substrate, on the second side of which the elements are defined and a thermal oxide layer is provided. While thinning the substrate, the active area of the semiconductor elements is protected against the etching means (wet or dry) by a hard mask. As a result, the device is provided with a mesa on its first side.

In a second technology, use is made of a substrate with a buried oxide layer. A well-known example of such a substrate is a silicon-on-insulator (SOI) substrate. The use of an SOI substrate allows the resulting device to be not just bendable, but completely flexible. This is particularly advantageous for identification labels, in which the presence of an integrated circuit is preferably kept secret. In this case, an electrically insulating layer is present on the second side of the substrate, and the vertical interconnect extends through it. Instead of or in addition to an electrically insulating layer of an oxide, a passivation layer can be present, for instance a nitride and particularly a nitride provided with an LPCVD. This layer will prevent the diffusion of impurities, including water, from the environment to the devices after the removal of the substrate. As the base layer of this SOI substrate is meant as a support only, it will be clear for the skilled person that it is to be removed to provide the desired flexibility.

In a preferred embodiment, the interconnect structure is provided with a first and a second via pad, which are present in the non-active area, and at which pads the first and the second vertical interconnects respectively are present. Due to the provision of the vertical interconnects outside the active area of the semiconductor elements, chemical contamination and parasitic electrical interaction can be prevented or at least considerably reduced. Moreover, any cracking as a result of pressure differences or differences in thermal expansion is more easily prevented if the vertical interconnects are constructed outside the active area, that is in practice a multilayer stack of a number of thin and vulnerable layers. Particularly the second via pad has large-scale dimensions as compared to other patterns in the integrated circuit. It may be for instance about 10 by 10 micrometers or larger, as a consequence of the thickness of the support layer and an etching step through this support layer.

It is highly preferred that the via pads are present on the electrically insulating layer that is part of the substrate. This presence is advantageous for the stability. In a further embodiment, the via pads and the vertical interconnect comprise a ductile material, such as Al. The electrically insulating layer comprises an oxide layer by preference.

The support layer preferably comprises an organic material. Such a material can be chosen to be photosensitive. It can furthermore have a large thickness, for instance in the range from 5 to 20 microns, so as to provide the required support, but is nevertheless not detrimental to the flexibility. It may also have a low dielectric constant. This limits the parasitic capacity between the first and the second contact face. Alternatively, the dielectric constant can be amended and increased to desire. The resulting parasitic capacitor can be used as a tuning capacitor, which is particularly suitable in combination with a dipolar antenna.

In a further preferred embodiment, a support layer is present on the first side of the device as well. The device is therewith encapsulated on both sides in such a support layer. This has a considerable advantage in view of the bending properties. The device has turned out to be more sensitive to compressive stress than to elastic stress. The compressive stress may lead to microcracks in the semiconductor layer and/or the interconnect structure. By the provision of a support layer on the first side as well, the compressive stress can be relaxated to this support layer. As will be clear, the support layer thereto has sufficient elasticity.

The device of the invention can be suitably integrated in an identification label further incorporating an antenna for wireless transmission. Next to identification labels for use in logistics or in security of products such an identification label can be a security paper, and documents incorporating such paper, such as bank notes, passports and other tickets. As is well-known in the art, it appears preferable to attach an integrated circuit in a bank note to the security thread which is present in the bank note. The security thread may be used as a dipole antenna with any modifications needed. In view of the ease of assembly and its flexibility, the device of the invention is suited very well to this purpose. Furthermore, the parasitic capacitors between the first and second contact faces can be designed to function as a tuning capacitor for the desired frequency.

Alternatively, the device of the invention can be integrated in other apparatus, including an information carrier, such as a DVD or a CD, or even a smart card.

The coupling between the device of the invention and the antenna may be realized both as a DC coupling, for instance with anisotropically conducting glue, but also capacitively, in that the contact faces form capacitor electrodes together with the antenna It can be advantageous in that the semiconductor device is provided with glue before assembly. A particularly suitable glue is that type of which the adhesive force increases on heating.

It is a second object of the invention to provide a method of manufacturing a semiconductor device of the invention in a robust manner. This object is achieved in that the method comprises the steps of:

providing a substrate with a semiconductor layer and an electrically insulating layer, an integrated circuit provided with a plurality of semiconductor elements being defined in an active area, the semiconductor elements being mutually interconnected according to a desired pattern in an interconnect structure, which interconnect structure comprises a first and a second via pad, which via pads are present in an area that is laterally substantially outside the active area;

applying a support layer of an electrically insulating material on the second side and providing a contact window in the support layer corresponding to the second via pad;

applying electrically conductive material in a desired pattern on the second side, therewith providing a second contact face and a second vertical interconnect between the said contact face and the second via pad;

attaching the substrate on its second side to a carrier with removable attaching means;

thinning the substrate from the first side, so that the insulating layer of the substrate is exposed at least in some non-active areas laterally outside and around the active area;

providing a first contact face on the first side, which is connected to the first via pad through a first vertical interconnect extending at least through the insulating layer, and

removing the thus obtained semiconductor device from the carrier.

This method according to the invention leads to a semiconductor device that is similar to the one known from EP-A 1,256,983, but which has the clear advantage of having contacts both on the bottom and the top side.

It is particularly preferred to use an SOI-type substrate. In this case, the insulating layer is buried in the substrate. The substrate further comprises a base layer and the semiconductor layer, which base layer is removed in the thinning step and in and on a surface of which semiconductor layer the semiconductor elements are defined.

The first vertical interconnect can be provided as part of the integrated circuit or after the finalization of the thinning process. It is preferred to provide this first vertical interconnect before the processing, e.g. as part of the integrated circuit. This has the advantage that for none of the described method steps a high resolution is required.

Such low-resolution patterning can be done in assembly factories, that are cheaper in use than semiconductor wafer factories. If desired, the patterned support layer can be provided as well before transfer of the device to an assembly factory.

It is furthermore advantageous that a plurality of semiconductor devices is provided in a single operation, as is well known in the art. In order to improve the removal of the devices from the carrier, it is preferred that at the edges of the wafer the support layer is removed and an adhesive is applied instead.

These and other aspects of the method, the semiconductor device and the identification label of the invention will be further explained with reference to the Figures, in which:

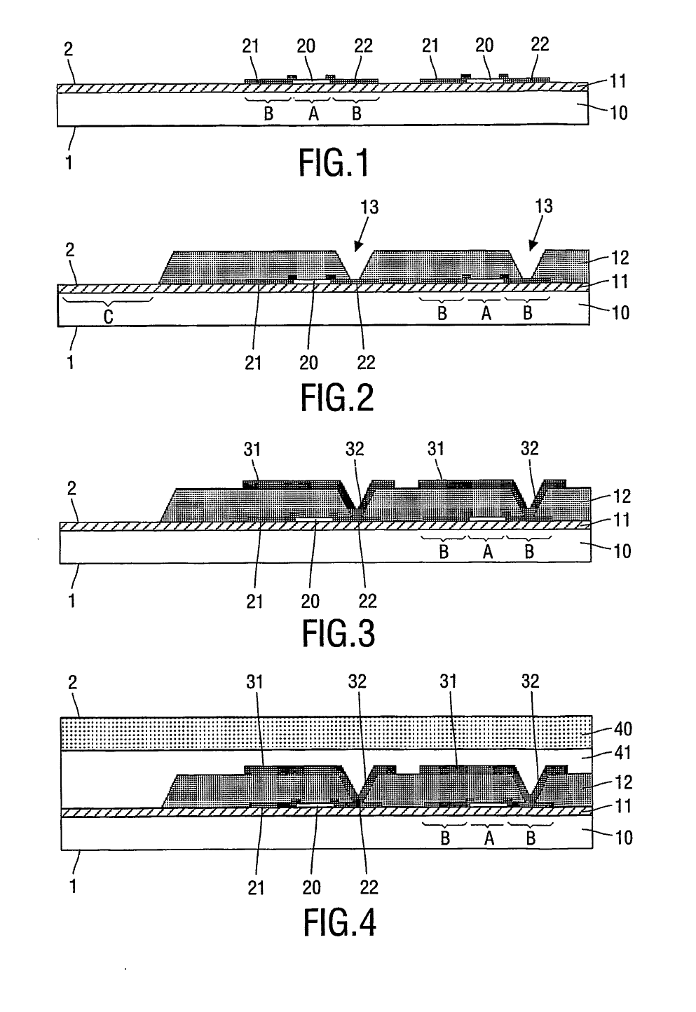

FIGS. 1 to 7 show cross-sectional views of several steps in a first embodiment of the method;

FIG. 8 shows a diagrammatical cross-sectional view of the semiconductor device in the first embodiment;

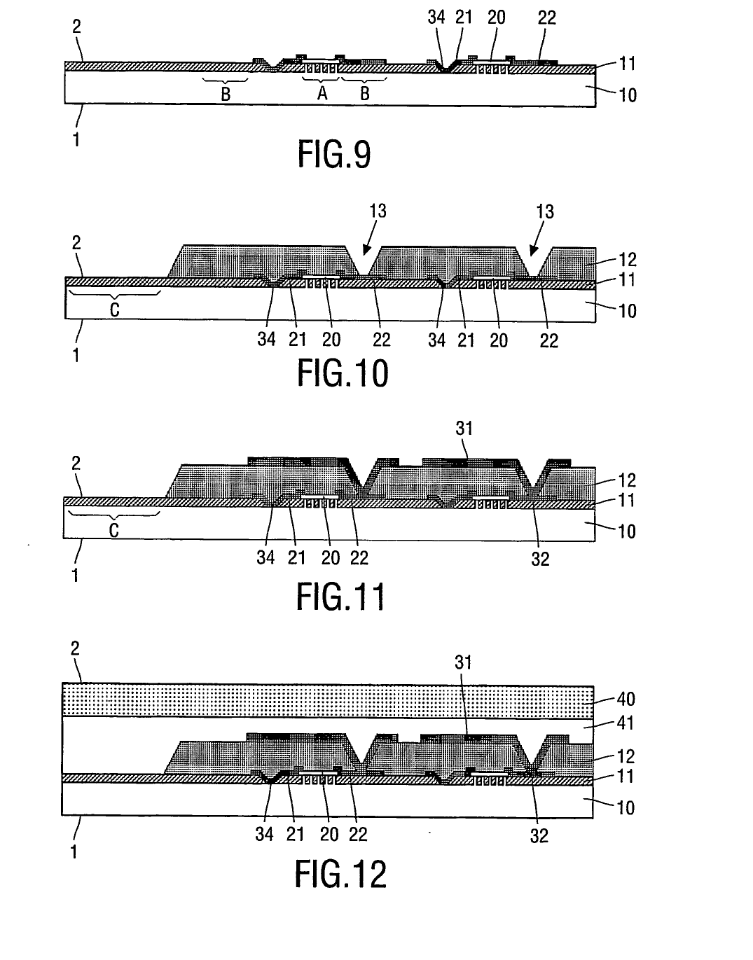

FIGS. 9-14 show cross-sectional views of several steps in a second embodiment of the method;

FIG. 15 shows a diagrammatical cross-sectional view of the semiconductor device in the second embodiment;

FIG. 16 shows a detail of FIG. 15; and

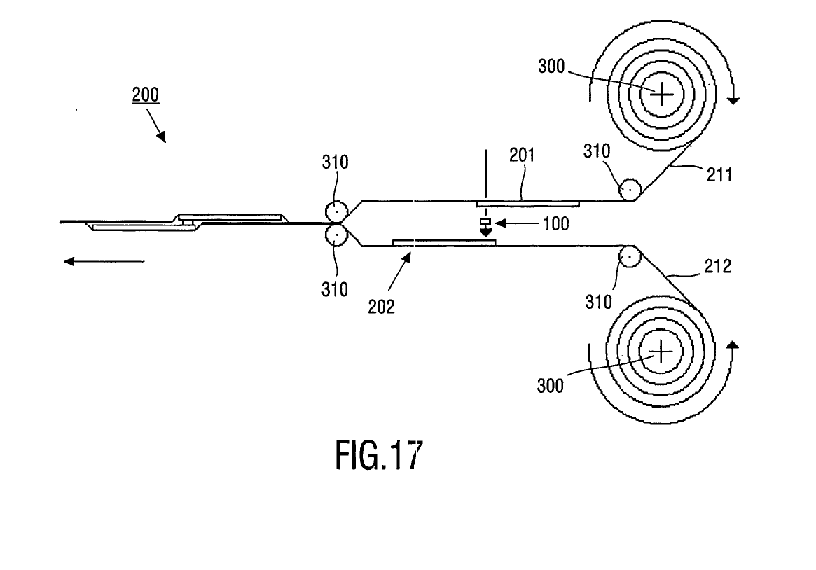

FIG. 17 shows a diagrammatical cross-sectional view of integration of the semiconductor device in the identification label.

The Figures are not drawn to scale and equal reference numerals refer to equal or similar parts.

FIGS. 1 to 7 relate to a first embodiment of the method of manufacturing a semiconductor device according to the invention. The resulting device is shown in FIG. 8.

In the first method of the invention, use is made of a substrate 10 in which an insulating layer 11 is buried. The buried layer 11 is typically an oxide layer, but includes preferably a nitride layer for improved chemical protection of the integrated circuit 20, which is provided in and on the semiconductor layer of a semiconductor material that is generally grown epitaxially. On the opposite side of the buried layer 11, a base layer is present. The semiconductor material of both the base layer and the semiconductor layer in the substrate 10 is silicon in this case. The integrated circuit 20 comprises a plurality of semiconductor elements (non-shown) in an active area A. The elements are mutually interconnected according to a desired pattern in an interconnect structure (not specifically shown). The structure comprises a first via pad 21 and a second via pad 22, which pads 21,22 are present in an area B that is laterally substantially outside the active area A. The via pads are preferably provided in a layer of aluminum in view of its ductility. However, Cu, Ni, Ag or a conductive paste could be used alternatively.

FIG. 2 shows the result after a support layer 12 of an electrically insulating material has been applied on the second side 2. In this case use is made of polyimide in a typical thickness of 10 to 20 μm. Before applying the polyimide, for instance by spincoating, the surface has been cleaned and a primer layer has been provided for improved adhesion. After the application of the polyimide, it is heated first to 125° C. and thereafter to 200° C. Then a photoresist is applied, exposed to a suitable source of radiation and developed. The development includes the structuring of the polyimide layer, so as to create contact windows 13 that expose the second via pads 22. The support layer 12 of polyimide is removed as well in an edge area C of the substrate, typically a 6″ wafer. The removal of the support layer 13 in the edge area C has a beneficial effect on the yield.

FIG. 3 shows the result, after an electrically conducting layer has been provided on the second side 2 of the substrate 10. The electrically conducting layer is applied in a pattern which comprises a second contact face 31 and a second vertical interconnect 32 between this contact face 31 and the second via pad 22. Preferably, the electrically conductive layer comprises Al. This, in combination with the use of Al for the second via pad 22, provides a good electrical connection and has the required flexibility to withstand any bending of the foil and any forces during lamination of the device into a label.

FIG. 4 shows the substrate 10 after it has been attached to a carrier 40 with removable attaching means 41. This means 41 is in this case a layer of adhesive, which is releasable upon irradiation with UV-radiation. Thereto, the carrier 40 is transparent, and in this example a layer of glass. It is preferred to apply a layer of an oxide on the support layer and the second contact face 31 and the interconnect 32. The advantage hereof is again the yield improvement. If desired, this layer can be provided according to a desired pattern. Thereafter, the edge area C is primered. The result hereof is a good adhesion between adhesive 41 and the support layer 12 in the edge area C, and a substantially weak adhesion in other areas.

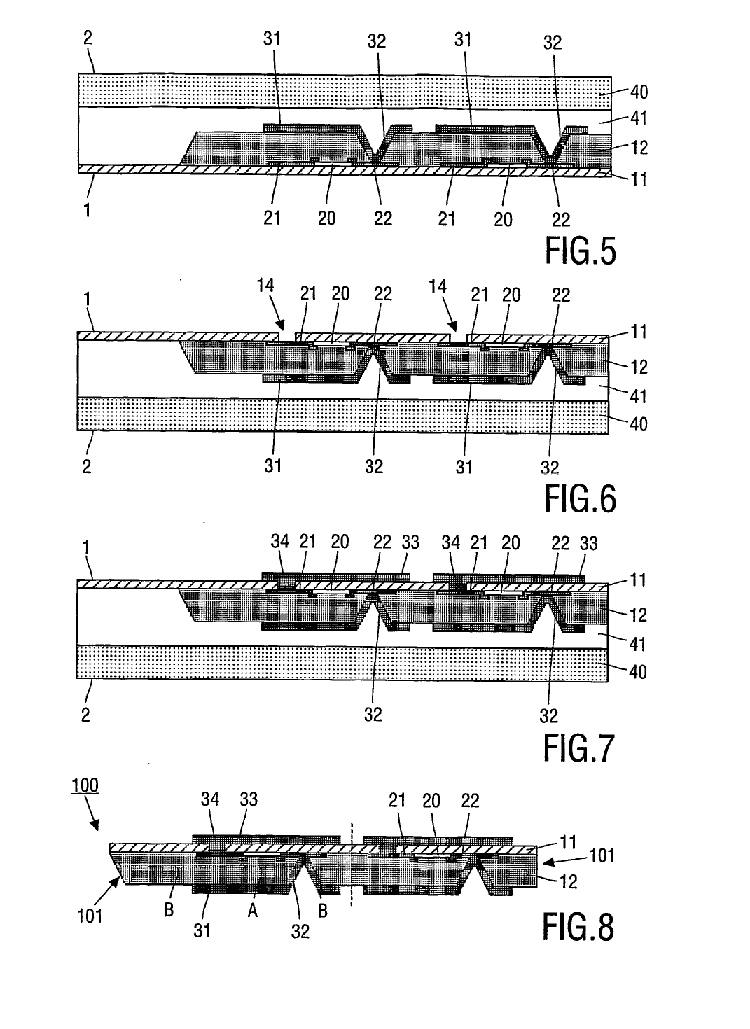

FIG. 5 shows the result after the substrate 10 has been thinned from the first side. This thinning is usually achieved by grinding and continued etching with KOH. The thinning is continued until the base layer of the substrate 10 is removed. The buried layer 11 acts herein as the etch stop layer.

FIG. 6 shows the result after patterning the buried oxide layer has been patterned so as to create contact windows 14.

FIG. 7 shows the result after applying a further metal layer, by which a first vertical interconnect 34 and a first contact face 33 are created. The further metal layer comprises for instance Al or Cu. In the case of Cu, a barrier layer may be applied so as to prevent any contamination of the semiconductor layer. After removal of the carrier 40 the individual devices 100 can be separated.

FIG. 8 shows the device 100 of the invention in a first embodiment. The device 100 comprises a first contact face 33 and a second contact face 31, as well as an integrated circuit 20. The integrated circuit is provided with vertical interconnects 32, 34 for establishing connections to the contact faces 31, 33. The device 100 is provided with an active area A and a non-active area B. It is supported by a support layer 12. The semiconductor layer of the substrate 10 is present in the active area A only. In this case, the only parts left of the substrate are the epitaxially grown semiconductor layer in the active area, and the electrically insulating layer 11. Due to the absence of the semiconductor layer and any part of the base layer in the non-active area B, it is prevented that any undesired electrical contact is made through the side face 101 of the device 100. The support layer 12 herein has a typical thickness of about 5-15 μm, preferably about 10 μm, and the contact faces 31,33 have a thickness of about 0.2-1.5 μm, preferably about 1.0 μm.

FIGS. 9 to 14 show a second embodiment of the method of the invention. This method comprises a number of steps which are equal to those in the first method. A major difference is the substrate 10, however. In this example it is a substrate of monocrystalline or polycrystalline silicon without any buried oxide layer. The oxide layer 11 is present on the second side of the substrate 10 and is used at the same time as gate oxide layer of the semiconductor elements within the integrated circuit 20. The semiconductor elements have been defined on the surface of the-substrate 10 in known manner, e.g. by implanted dopants of a selected material in a required concentration. Also implanted is a well extending through part of the substrate 10 towards the first side 1. On top of this well the oxide layer 11 has been patterned and an electrical connection is made. This constitutes a first vertical interconnect 34 to a first contact face to be provided in a later stage of the process. In addition to the interconnect 34 a first via pad 21 and a second via pad 22 are defined. These via pads 21,22 are located outside an active area A, and not necessarily but probably partly in a non-active area B.

FIG. 10 shows the result after a flexible support layer 13 has been applied, cured and patterned in a desired manner so as to remove it from an edge area C and so as to create contact windows 13 to the second via pads 22.

FIG. 11 shows the result after an electrically conductive material has been applied in a desired pattern on the second side on top of the support layer 12, therewith defining the second contact faces 31 and a vertical interconnect 32 to the second contact pad 22.

FIG. 12 shows the result after the structure has been attached to a carrier 40 with an adhesive 41.

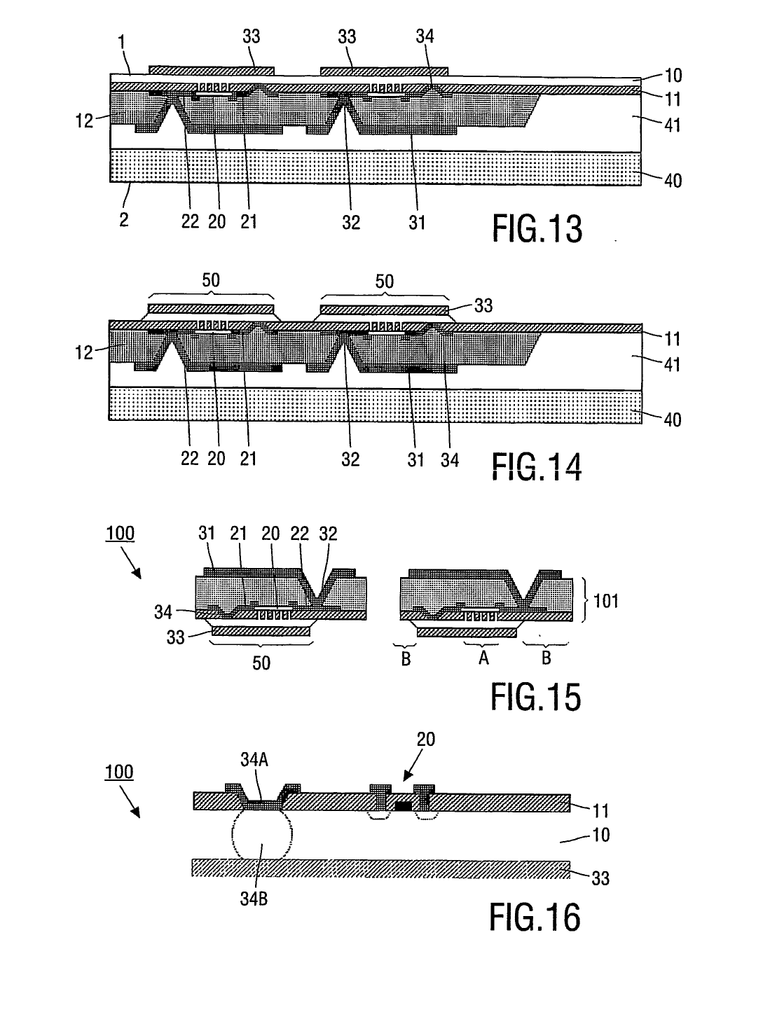

FIG. 13 shows the result after the substrate 10 has been thinned from the first side 1 and an etch mask 33 has been applied. This etch mask is made from an electrically conductive material, and will subsequently function as the first contact face. The contact to the first contact pad 21 is herein made through the well through the substrate 10, which is part of the vertical interconnect 34. This is shown in more detail in FIG. 16, which shows the substrate 10, an element of the integrated circuit 20 and the vertical interconnect 34, that is formed by the metal trace 34A and the well 34B through the substrate 10.

FIG. 14 shows the result after the substrate 10 is etched from the first side, and in this manner a mesa 50 is created. The mesa 50 further defines the non-active area B, which is present outside the mesa, and in which the semiconductor substrate 10 is absent. It is observed that the via 34 may be present outside the mesa 50. In this case, the via 34 is formed in that after the forming of the mesa an electrically conductive layer is provided on the first side 1 of the substrate according to a desired pattern.

FIG. 15 shows the resulting semiconductor device 100, having an active area A and a non-active area B. It is to be noticed that in this case there is a further area between the non-active area B and the active area A. The device 100 comprises first and second contact faces 31, 33 and vertical interconnects 32,34 for connecting the faces 31,33 to the integrated circuit 20.

FIG. 17 shows a method of integration of the semiconductor device 100 of the invention into an identification label 200. The label 200 is manufactured by laminating a first foil 211 and a second foil 212. The foils are provided on rolls 300, and the laminating process is structured through wheels 310. The foils 211, 212 are each provided with a plurality of conductive patterns 201, 202, which are able to act as an antenna, for instance a dipole antenna In this method, the semiconductor device 100 is provided between the foils. Adhesive may be present on either the semiconductor device 100 or the foils 201,202 so as to improve the attachment. The semiconductor device 100 is provided on the foils without a specific orientation. Due to the absence of the semiconductor substrate 10 in the non-active area B, there is no risk of one of the conductive patterns 201,202 being in electrical contact with both the first contact face and the second contact face of the device, or there being a substantial parasitic capacitance due to the interaction through the semiconductor substrate. The pattern in the foil 201, 202 could further be designed to be a security thread.

It is a further advantage of the device of the invention, that the active area hereof is protected against the forces during lamination into the label. In this lamination, the largest forces are exerted in the metal areas, which are the vertical interconnects. These are however outside the active area A, and any forces will be lead further to the support layer. As this support layer has free surfaces on the side faces of the device, it is able to relaxate such forces. Also, the V-shaped second vertical interconnect appears to reduce negative effects of the pressure during lamination.

In short, the semiconductor device 100 of the invention comprises an integrated circuit 20 and a first and a second contact face 31,33. These are connected with vertical interconnects 32,34 to the integrated circuit 20. This integrated circuit 20 is present in a semiconductor layer of a substrate. This substrate is absent in a nonactive area B. This leads to the fact that on the side faces 101 of the device 100 neither conductive material nor parts of the semiconductor substrate are exposed. On lamination of the device between two metallized foils into an identification label, the risk of short-circuitry due to undesired contact on the side face 101 of the device 100, is prevented thereby.

1. A semiconductor device having a first and an opposite second side, comprising:
a substrate comprising a semiconductor layer and an electrically insulating layer, and being present on the first side of the device;
an integrated circuit provided with a plurality of semiconductor elements, which are defined in and/or on the semiconductor layer and are interconnected according to a desired pattern in an interconnect structure;
a first contact face that is present on the first side of the device;
a second contact face that is present on the second side of the device, and is connected to the interconnect structure;
wherein:
an electrically insulating support layer is present, which covers on the second side the integrated circuit and extends laterally around the integrated circuit in a non-active area, through which support layer a vertical interconnect is present to connect the second contact face with the interconnect structure;
the semiconductor layer of the substrate is laterally partially removed so as to be absent in the non-active area; and
the first contact face is connected to the interconnect structure through a vertical interconnect.

2. A semiconductor device as claimed in claim I, characterized in that the vertical interconnect to the first contact face is present in the non-active area, the first contact face being defined in an electrically conducting layer.

3. A semiconductor device as claimed in claim 1, characterized in that the electrically insulating layer is laterally substantially continuous so as to be present in the non-active area.

4. A semiconductor device as claimed in claim 1, characterized in that the interconnect structure is provided with a first and a second via pad, which are present in the non-active area, and at which pads the first and the second vertical interconnects respectively are present.

5. A semiconductor device as claimed in claim 4, wherein the via pads are present on the electrically insulating layer that is part of the substrate.

6. A semiconductor device as claimed in claim 4, characterized in that the second via pad and the second vertical interconnect comprise a ductile material.

7. A semiconductor device as claimed in claim 1, characterized in that the support layer comprises an organic material.

8. An identification label comprising the semiconductor device according to claim 1 and an antenna for wireless transmission.

9. An information carrier comprising the semiconductor device according to claim 1.

10. A method of manufacturing a semiconductor device comprising the steps of:
providing a substrate with a semiconductor layer and an electrically insulating layer, an integrated circuit provided with a plurality of semiconductor elements being defined in an active area, the semiconductor elements being mutually interconnected according to a desired pattern in an interconnect structure, which interconnect structure comprises a first and a second via pad, which via pads are present in an area that is laterally substantially outside the active area;
applying a support layer of an electrically insulating material on the second side and providing a contact window in the support layer corresponding to the second via pad;
applying electrically conductive material in a desired pattern on the second side, therewith providing a second contact face and a second vertical interconnect between said contact face and the second via pad;
attaching the substrate on its second side to a carrier with removable attaching means;
thinning the substrate from the first side, so that the insulating layer of the substrate is exposed at least in some non-active areas laterally outside and around the active area;
providing a first contact face on the first side, which is connected to the first via pad through a first vertical interconnect extending at least through the insulating layer; and
removing the thus obtained semiconductor device from the carrier.

11. A method as claimed in claim 10, wherein the oxide layer is buried inside the semiconductor substrate, the substrate further comprising a base layer and an active layer, which base layer is removed in the thinning step and on a surface of which active layer the semiconductor elements are defined.

12. A method as claimed in claim 10, wherein the first vertical interconnect is provided as part of the integrated circuit.
